(19) United States
(12) Patent Application Publication
(10) Pub. No.: US 2025/0087459 A1
(43) Pub. Date: Mar. 13, 2025

(54) TUNABLE PATTERNED SURFACE UNIFORMITY USING DIRECT CURRENT BIAS

(71) Applicant: Tokyo Electron Limited, Tokyo (JP)

(72) Inventor: Pingshan Luan, Albany, NY (US)

(21) Appl. No.: 18/466,613

(22) Filed: Sep. 13, 2023

(51) Int. Cl. H01J 37/32

(52) U.S. Cl. CPC H01J 37/32128; H01J 37/32091; H01J 37/32146; H01J 37/32174; H01J 2237/334

(57) ABSTRACT

A high aspect ratio etching method includes generating plasma in a chamber containing a substrate including a patterned surface such as a hardmask, and etching one or more underlying layers through openings in the patterned surface by coupling a periodic sequence including direct current bias waveforms to the substrate. Each bias waveform has voltage ranging from a reference voltage to a peak voltage. The periodic sequence has a duty cycle greater than 20%. The bias waveforms may include a non-vertical voltage transition. The one or more underlying layers may be a dielectric and the method may be a high aspect ratio contact etch. The etching may form features having an aspect ratio of at least about 100:1 and a critical dimension less than about 100 nm. The periodic sequence may have a frequency between about 100 kHz and about 3 MHz.

### TECHNICAL FIELD

The present invention relates generally to high aspect ratio etching, and, in particular embodiments, to systems and methods for high aspect ratio etching using direct current bias waveforms.

### BACKGROUND

Microelectronic device formation may involve a series of manufacturing techniques including formation, patterning, and removal of a number of layers of material on a substrate. Etch masks may be formed (e.g., deposited) to protect regions of the substrate and allow for pattern transfer via etching. Obtaining a high aspect ratio during etching is important for a variety of semiconductor processes such as during high aspect ratio contact (HARC) formation. For example, high aspect ratio (HAR) etch processes (e.g., HARC) with an aspect ratio of 100:1 and higher may be required for certain applications, such as memory formation (e.g., high-capacity three-dimensional (3D) memory applications). In addition to high aspect ratio requirements, critical dimension (CD) requirements for HARC etch processes are also becoming more demanding, with feature sizes less than 100 nm.

Achieving mask uniformity during HAR etch processes is challenging with high aspect ratios, low CD, and high feature density. Controlling the mask uniformity is important to achieve consistent pattern transfer to the underlying layer. Small variations at a mask opening (e.g., a hole) may be amplified as the etch proceeds through the mask resulting in feature distortion or even failure to reach the underlying layer. Controlling local mask uniformity (e.g., the variation of features across a single substrate or region of a substrate) is challenging because the etch process itself must be carefully controlled, such as through precise control of process parameters such as source and bias power, gas flow rate, pressure, temperature, etc.

Local critical dimension uniformity (LCDU) measures variations in the CD across different features of the same substrate (e.g., a wafer) or region of the substrate (e.g., a chip). For holes, local uniformity of the circularity (e.g., one minus ellipticity, the ratio between the major axis and the minor axis of an ellipse that fits in the hole) is also important. Less circular holes in the mask may result in alignment issues and undesirable contact resistance variation (in the case of contact etches).

Bias power may be applied during HAR etch processes (e.g., coupled to substrate such as a wafer through a substrate support such as a chuck) to create a potential difference between the plasma and the substrate surface. Ions may be accelerated through the resulting plasma sheath towards the substrate surface. However, mask uniformity could be lacking when bias power is applied using conventional methods. Furthermore, conventional methods can also be unable to achieve desired aspect ratios, especially for low CDs. Therefore, methods of applying bias power during HAR etch processes that improve mask uniformity for high aspect ratios and low CDs, such as by improving the tuning capabilities of the etch process, are desirable.

### SUMMARY

In accordance with an embodiment of the invention, a method for high aspect ratio etching includes generating a plasma in a plasma etching chamber containing a substrate including a patterned surface, and etching one or more underlying layers through openings in the patterned surface by coupling a periodic sequence including direct current (DC) bias waveforms to the substrate. Each of the DC bias waveforms including a non-vertical voltage transition and voltage ranging from a reference voltage to a negative peak voltage. The periodic sequence has a duty cycle greater than 20%.

In accordance with another embodiment of the invention, a method for high aspect ratio dielectric etching includes generating a plasma in a plasma etching chamber containing a substrate including a hardmask overlying a dielectric by applying a radio frequency (RF) signal to a source power coupling element, and etching the dielectric through openings in the hardmask to form features having an aspect ratio of at least about 100:1 by coupling a periodic sequence including DC bias waveforms to a lower electrode supporting the substrate with frequency between about 100 kHz and about 3 MHz. Each of the DC waveforms has voltage ranging from a reference voltage to a negative peak voltage less than or equal to about −7 kV. The periodic sequence has a duty cycle greater than 20%.

In accordance with still another embodiment of the invention, a system for high aspect ratio etching includes a plasma etching chamber, an RF power supply configured to generate an RF signal, a source power coupling element coupled to the RF power supply and configured to generate a plasma within the plasma etching chamber using the RF signal, a lower electrode disposed in the plasma chamber and configured to support a substrate, a DC power supply configured to supply DC voltage, a DC waveform generator coupled between the lower electrode and the DC power supply, and a controller coupled to the DC waveform generator and configured to cause the DC waveform generator to generate a periodic sequence. The DC waveform generator is configured to etch the substrate by generating the periodic sequence of DC waveforms having voltage ranging from a reference voltage to an absolute peak voltage of at least about 7 kV. The periodic sequence has a frequency between about 100 kHz and about 3 MHz and a duty cycle greater than 20%.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example process for high aspect ratio etching of one or more underlying layers of a substrate through openings of a patterned surface using direct current (DC) waveforms in accordance with embodiments of the invention;

FIG. 2 illustrates an example system for high aspect ratio etching that includes a DC waveform generator coupled to a lower electrode supporting a substrate within a plasma etching chamber in accordance with embodiments of the invention;

FIG. 3 illustrates a comparison between impact angles between different profiles of material deposited on the patterned surface during a high aspect ratio etching process in accordance with embodiments of the invention;

FIG. 4 illustrates waveform tuning of a high aspect ratio etching process with a qualitative graph of the etch rate and deposition rate versus the impact angle for various waveform shapes in accordance with embodiments of the invention;

FIG. 5 illustrates duty cycle tuning of a high aspect ratio etching process with a qualitative graph of the etch rate and deposition rate versus the impact angle for various duty cycles in accordance with embodiments of the invention;

FIG. 6 illustrates voltage tuning of a high aspect ratio etching process with a qualitative graph of the etch rate and deposition rate versus the impact angle for various peak voltages in accordance with embodiments of the invention;

FIG. 7 illustrates an example patterned surface and corresponding etched features where the openings in the patterned surface are holes in accordance with embodiments of the invention;

FIG. 8 illustrates an example patterned surface and corresponding etched features where the openings in the patterned surface are trenches in accordance with embodiments of the invention;

FIG. 9 schematically illustrates a comparison between uniform holes in a patterned surface and irregular holes in a patterned surface in accordance with embodiments of the invention;

FIG. 10 illustrates an example qualitative graph of a periodic sawtooth sequence that includes sawtooth waveforms in accordance with embodiments of the invention;

FIG. 11 illustrates an example qualitative graph of a periodic triangular sequence that includes triangular waveforms in accordance with embodiments of the invention;

FIG. 12 illustrates an example qualitative graph of a mixed periodic sequence that includes a mixture of arbitrary waveforms in accordance with embodiments of the invention;

FIG. 13 illustrates an example system for high aspect ratio etching where the system is implemented as a capacitively coupled plasma etching system in accordance with embodiments of the invention;

FIG. 14 illustrates an example system for high aspect ratio etching where the system is implemented as an inductive coupled plasma etching system in accordance with embodiments of the invention;

FIG. 15 illustrates example qualitative graphs of an RF signal, a periodic sequence, and a combined RF power and DC bias waveform in accordance with embodiments of the invention; and

FIG. 16 illustrates a method for high aspect ratio etching in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Modern semiconductor structures have become more vertical as well as more dense. As a result, various applications (e.g., high capacity 3D memory applications) use HAR etch processes that have an aspect ratio equal to or higher than 100:1. The high feature density also lowers the CD for HAR etch processes with many processes having a CD less than 100 nm (e.g., 70 nm). Therefore, HAR etch processes meeting these aspect ratio and CD requirements with high pattern transfer fidelity all the way from top mask to the underlying layer (e.g., bottom contact) are desired. Good mask LCDU is an important factor for defect control and yield improvement. Various methods may be employed to improve mask uniformity, such as additive gas precursors, wafer temperature control, and energetic DC electrons, but these methods usually come at the cost of selectivity, etch rate, and etch profile distortion. Additionally, they do not allow precise enough control over mask uniformity.

How bias power is applied to the wafer during HAR etch processes can affect the mask LCDU. The conventional method of applying bias power is as radio frequency (RF) power, such as in the low frequency (LF) portion of the electromagnetic spectrum. The RF bias power has a sinusoidal shape and thus a corresponding smooth (and gradual) transition between high voltage and low voltage portions of the waveform. The potential difference between the plasma and the substrate imparts energy to the ions. Due to the sinusoidal shape, the ion energy and angular distributions of incoming ions on the wafer are relatively broad.

With the increase of the aspect ratio and the shrinking of CD size, controlling mask defects, such as distortion, necking, bowing, and low LCDU, becomes increasing difficult which drives the demand for new process regimes and tunability of the tool. Additionally, because of the limitations in mask uniformity, high aspect ratio (e.g., 100:1 and higher) etch processes frequently fail due to the stochastically clogged and bridged etch features. Therefore, new control schemes on etch tools that offer pattern transfer with excellent fidelity and uniformity, such as for high aspect ratios (e.g., 100:1 and higher) with small CD (e.g., 100 nm and smaller), are highly desirable.

Although the conventional sinusoidal RF bias power scheme excels in simplicity and cost-effectiveness, it leaves out promising parameter space (e.g., there is no control over duty cycle, waveform shape, etc.) for further process tuning. Such additional control can be obtained by applying bias power as a periodic sequence of rectangular direct current (DC) pulses at a desired frequency (e.g., in the tens of kHz to MHz range). That is, each DC pulse is “on” for a portion of the cycle (pulse on time) and “off” for a portion of the cycle (pulse off time). The duty cycle of the bias power is the ratio of the pulse on time to the period of the cycle. The rectangular bias power increases the amount of time that ions are being accelerated at high voltage to the substrate which narrows the ion energy and angular distribution. In this regard, rectangular bias power may be considered an improvement over sinusoidal RF bias power. However, generating high quality rectangular waveforms can be complicated and require expensive hardware.

In accordance with various embodiments herein described, the invention proposes an improved method for applying bias power to a substrate during a high aspect ratio etching process. The bias power is applied as periodic sequences of arbitrary DC bias waveforms with a combined duty cycle greater than 20%. Specifically, the DC bias waveforms are arbitrary in the sense that any desired waveform shape may be chosen (as opposed to be arbitrary in the sense that the shape has no effect). For example, in some cases, the waveform shape may be used to tune etch rate and mask uniformity as well as to lower power usage and hardware cost. The combination of arbitrary DC bias waveforms applied at a duty cycle greater than 20% may advantageously improve feature uniformity, especially LCDU, such as in patterned surfaces (e.g., hardmasks).

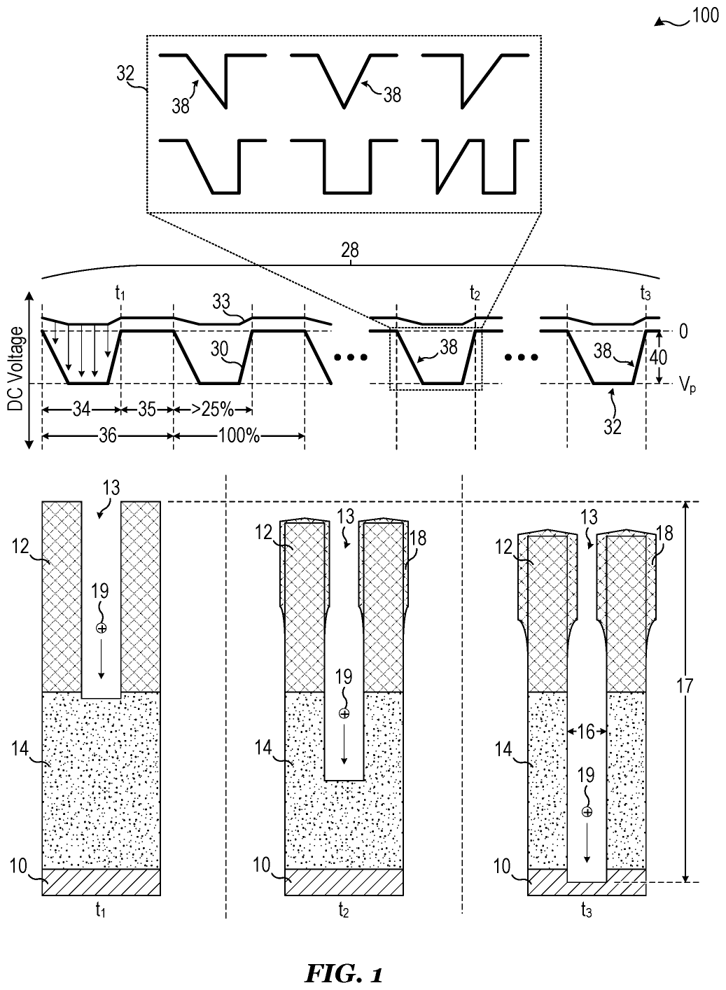

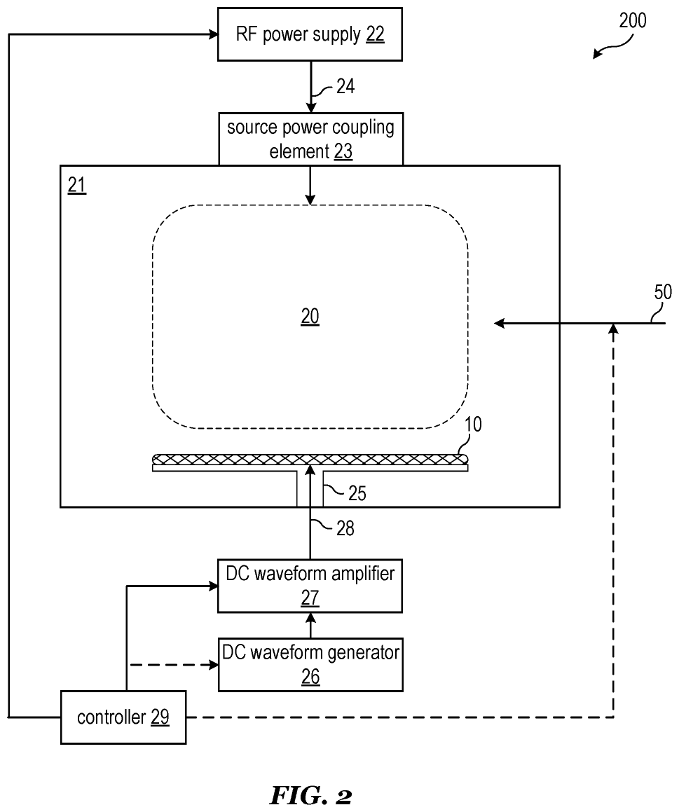

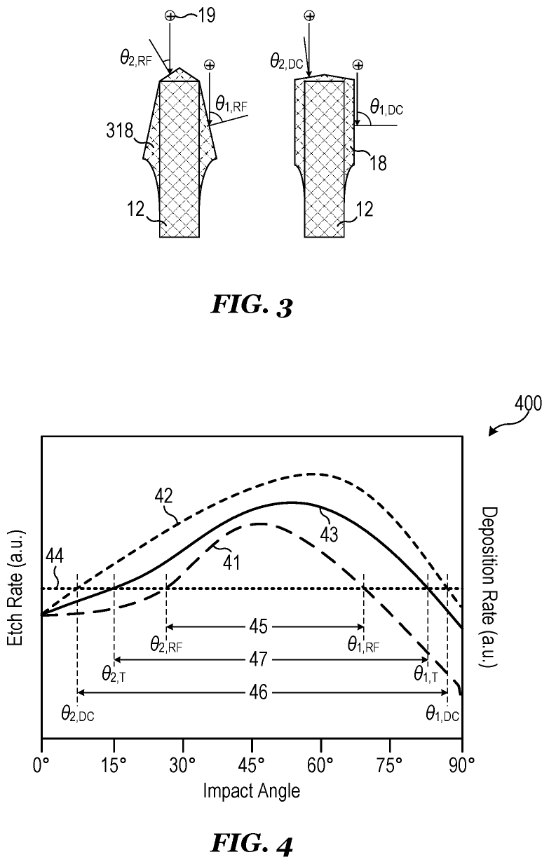

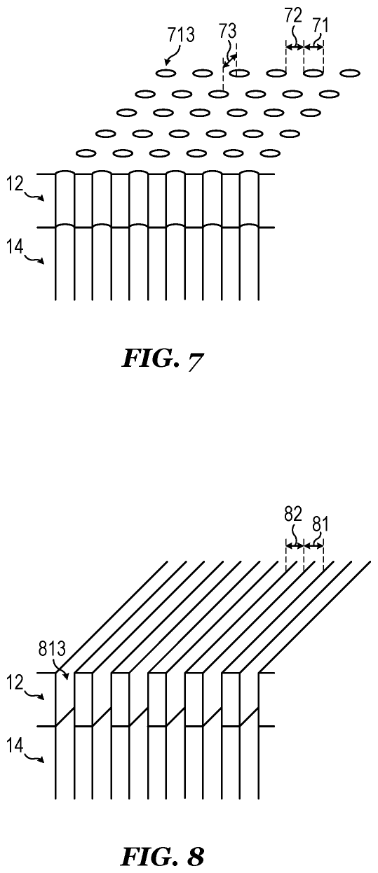

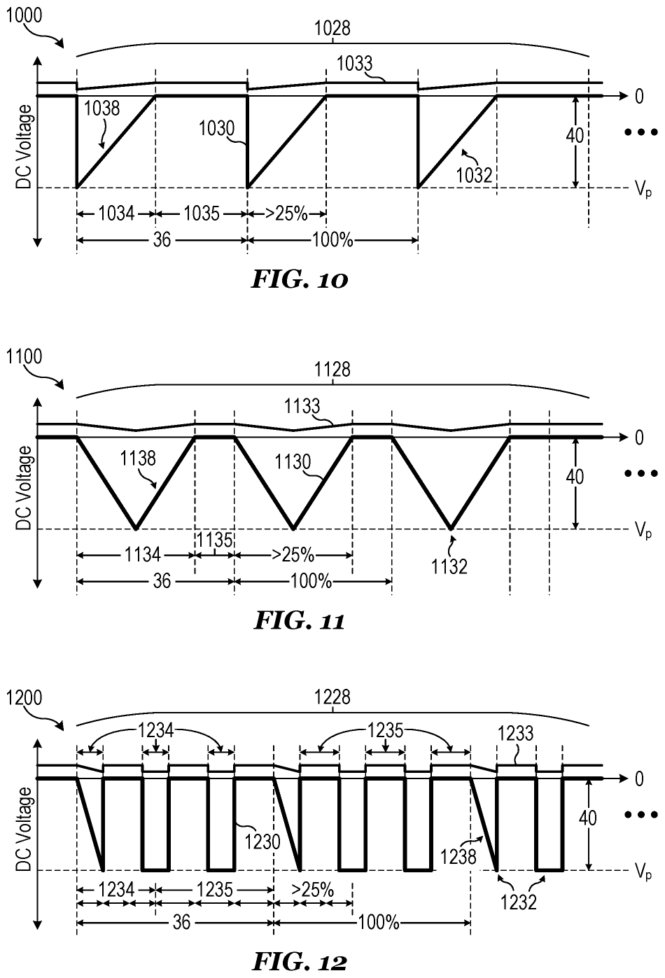

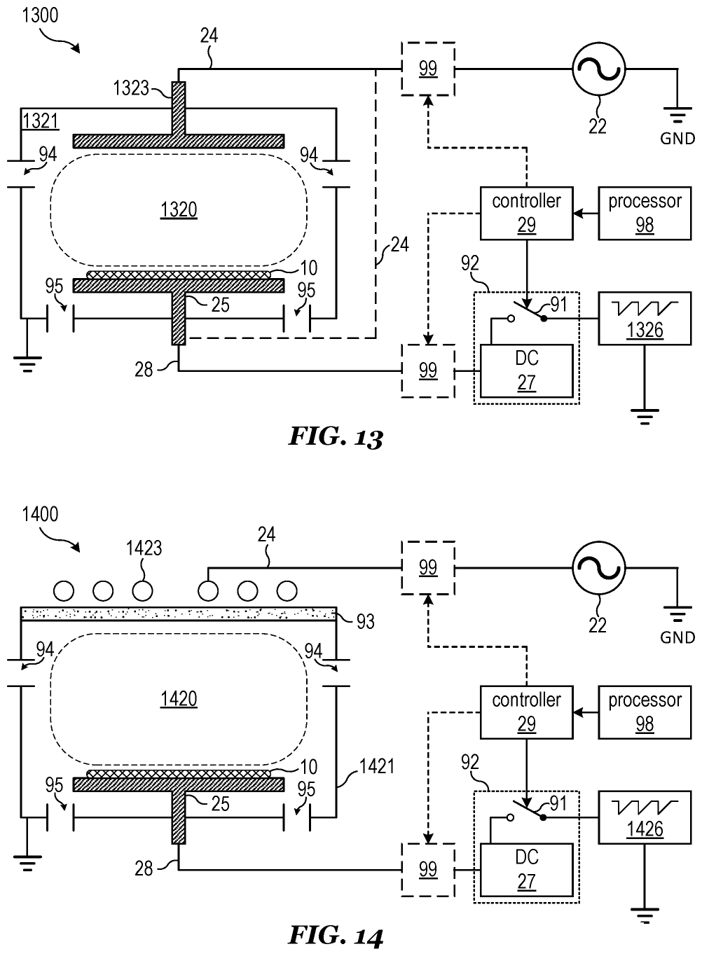

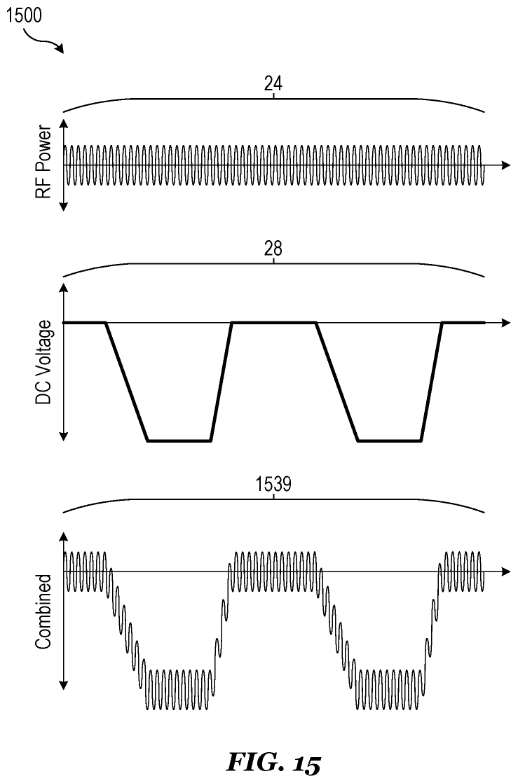

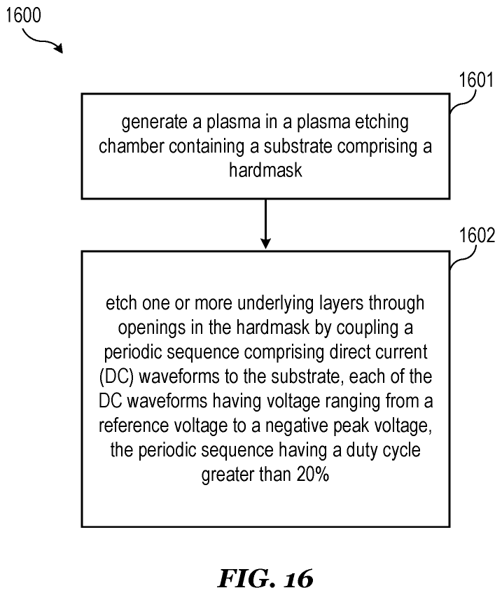

Embodiments provided below describe various methods and systems for high aspect ratio etching, and in particular embodiments, to methods and systems for high aspect ratio etching that include the use of a periodic sequence of DC bias waveforms with duty cycle greater than 20%. The following description describes the embodiments. FIG. 1 is used to describe an example high aspect ratio etching process. FIG. 2 is used to describe an example high aspect ratio etching system. Different profiles of material deposited during a high aspect ratio etching process are described using FIG. 3. FIGS. 4-6 are used to describe tuning of a high aspect ratio process using waveform shape, duty cycle, and voltage, respectively. Three example patterned surfaces are described using FIGS. 7-9. Several example periodic sequences of DC bias waveforms are described using FIGS. 10-12 while two more example high aspect ratio systems are described using FIGS. 13 and 14. An example of a combined RF power and DC bias waveform is described using FIG. 15. An example method for high aspect ratio etching is described using FIG. 16.

FIG. 1 illustrates an example method for high aspect ratio etching of one or more underlying layers of a substrate through openings of a patterned surface using direct current (DC) waveforms in accordance with embodiments of the invention.

Referring to FIG. 1, a process 100 for high aspect ratio etching includes coupling a periodic sequence 28 of DC bias waveforms 32 to a substrate 10. The substrate 10 includes a patterned surface 12 (e.g., a hardmask with openings 13 patterned therein). High aspect ratio features are formed by etching one or more underlying layers 14 through the openings 13 in the patterned surface 12. While the periodic sequence 28 is coupled to the substrate 10, the voltage 30 at the substrate 10 ranges between a reference voltage (here, shown as 0 V) and a peak voltage 40 (V_{P}), which may be negative, as shown.

The patterned surface 12 may be implemented as a hardmask that is used in semiconductor processing as an etch mask instead of a polymer or organic material. For example, polymers may tend to be etched too easily by reactive gases (e.g., oxygen, fluorine, chlorine, and others) so that the mask pattern rapidly degrades and the aspect ratio is severely limited. In various embodiments, the patterned surface 12 is a carbon-based hardmask and is an amorphous carbon layer (ACL) in one embodiment. In another embodiment, the patterned surface 12 is a hardmask comprising a tungsten silicide (WSi) layer. Of course, other materials and mask types are also possible.

The one or more underlying layers 14 include a dielectric in various embodiments and include an oxide in some embodiments. The one or more underlying layers 14 include silicon oxide (SiO₂) in on embodiment. The one or more underlying layers 14 includes a nitride in some embodiments and includes silicon nitride (Si₃N₄) in one embodiment. For example, the one or more underlying layers 14 may be alternating layers of oxide and nitride (ONO layers).

The voltage 30 (e.g., the wafer potential) affects the plasma potential 33, but the mobility of electrons is typically much higher than that of the ions 19 used for etching the underlying layers 14. As a result, when the voltage 30 goes below the reference potential, a plasma sheath is formed from electrons vacating a region of the plasma near the substrate 10. The ions 19 that remain in the sheath (and any ions 19 that enter the sheath from random thermal motion) are accelerated toward the substrate 10 by the electric field caused by the difference in the voltage 30 and the plasma potential 33 (schematically indicated by arrows in the leftmost waveform and in the openings 13).

Because the ions 19 are accelerated by electric field, the sheath potential (difference between voltage 30 and plasma potential 33) may be used as an estimation of the ion energy that is bombarding the substrate 10. It may be desirable to have high ion energy bombarding the substrate 10 for as long as possible. In this way, a large number of the ions 19 (i.e., a large ion flux) will be present at the etch front to etch the one or more underlying layers 14.

Verticality of ions can be controlled using the bias voltage. For example, higher voltages may impart more energy to the ions which widens the gap between the thermal ion energy (random motion) and the ion energy derived from the applied bias voltage (directional motion towards the substrate). Therefore, in general, the impact angle (i.e., the angle between the velocity vector of the ions and the normal of the surface being etched) will decrease (i.e., the ions become more vertical) as the voltage is increased.

The energy imparted to the ions may also depend on the duration that the voltage is applied. Specifically, the applied bias voltage causes a potential difference between the plasma potential and the wafer potential. This potential difference (sheath voltage) accelerates the ions towards the substrate (the ions gain kinetic energy from the applied voltage). If the voltage is applied for a sufficient amount of time (e.g., long enough for ions to be accelerated through the entire plasma sheath), then the ion energy distribution will be narrowed, with the majority of the ions reaching the substrate passing through the entire sheath, and only broadened by the thermal energy of the ions (e.g., ion temperature). Therefore, it may be desirable that each application of bias voltage during a cycle be long enough to move ions through the entire plasma sheath.

The periodic sequence 28 has a period 36 including the sum of the duration of each DC bias waveform 32 and the off time 35 between the DC bias waveforms 32. The percentage of time that the voltage 30 is not at the reference voltage is the duty cycle 34, and is greater than 20% for the periodic sequence 28. A waveform extending the whole period 36 would have a 100% duty cycle and be continuous wave (CW) DC bias power.

However, there are problems with substrate charging when applying DC power (the substrate and the layers formed thereon may be unable to dissipate charge fast enough to avoid collected a charge over time). Additionally, the substrate acts as a capacitor (e.g., when insulative material, such as SiO2 and Si3N4, is in the one or more underlying layers 14). As a result, there is a balance between duty cycle and voltage since as the capacitor charges the effective difference between the plasma potential and the substrate potential becomes smaller and smaller. Overheating and arcing may also be an issue when the duty cycle is high. While this could be combatted by including an advanced cooling system and/or high-k material selection, efficiency and cost savings would then be nullified. For this reason, a duty cycle between about 20% and about 60% may be reasonable and may extend up to an 80% duty cycle in some cases.

Optionally, each of the DC bias waveforms 32 may include a non-vertical voltage transition 38 (e.g., a transition that is not substantially vertical, as in square or rectangular waves). This transition may have any shape (e.g., linear, quadratic, exponential, irregular, etc.) and reflects the ability to choose an arbitrary waveform for the DC bias waveforms 32 while still achieving a high aspect ratio (e.g., 100:1 or higher) with small critical dimension (e.g., less than 100 nm) and high mask uniformity (e.g., LCDU with 3σ<6%) when the duty cycle is greater than 20%. Such transition of voltage shapes may naturally occur due to the characteristics of the power supply and the transmission lines connecting it to the plasma. This relaxation of waveform shape may further reduce the cost of the tool.

The ions 19 etch the underlying layers 14 to form features with a feature width 16 (which may be the critical dimension of the patterned surface 12). At a time t₁, after the first DC bias waveform 32 (or at least early in the application of the periodic sequence 28), the one or more underlying layers 14 are barely etched. Sometime later at a time t₂, the one or more underlying layers 14 have been etched further. The etching process may be complete at a time t₃ when the opening 13 reaches or proceeds some amount into the substrate 10 (or another layer that is not the etch target), as shown. Although other measures of aspect ratio are also possible, the aspect ratio may be defined as the feature width 16 divided by the total depth 17.

In some high aspect ratio etching processes material (e.g., polymer) is deposited on the patterned surface 12 while the underlying layers 14 are being etched. This forms a material buildup layer 18, that can take various shapes depending on the specifics of a given etching process. As shown, the material buildup layer 18 may take a substantially rectangular shape (akin to a shovel) that has a relatively flat top and nearly vertical sides. Such a shape may be advantageous to maintain an obstacle-free path for the ions 19 to travel through the opening with the least amount of deviation from the vertical.

The process 100 may provide a variety of advantages over conventional high aspect ratio etching methods. For example, the LCDU (e.g., of the dielectric for high aspect ratio dielectric etching processes) and the mask circularity (e.g., when the openings 13 are holes) may be improved using high negative bias voltage (e.g., less than about −7 kV) and a duty cycle greater than 20% with an arbitrary DC bias waveform applied at a low frequency (e.g., between about 100 kHz and about 3 MHz). In one embodiment, the periodic sequence 28 is applied with frequency of about 400 kHz. In another embodiment, the periodic sequence 28 is applied with frequency of about 200 kHz.

Additionally, the process 100 may require no alteration of the process temperature window (e.g., may be a room temperature process or compatible with typical process temperature windows) and require no advanced cooling system. For example, aspect ratios of greater than 90:1 for critical dimensions less than 100 nm may be achievable at 20° C.

As shown in the box above the periodic sequence 28, the DC bias waveforms 32 may have many different shapes, regular and otherwise. For example, the DC bias waveforms 32 have a sawtooth waveform shape in one embodiment. The sawtooth waveform may be either direction (e.g., linear rise or linear fall). In another embodiment, the DC bias waveforms 32 have a triangular waveform shape. In still another embodiment, the DC bias waveforms 32 have a trapezoidal waveform shape with a vertical voltage transition. In still yet another embodiment, the DC bias waveforms 32 have a rectangular waveform shape. Furthermore, irregular waveforms are also possible and waveform shapes may be mixed together in a single periodic sequence 28. However, it should be noted that if the duty cycle 34 is reduced below 20%, arbitrary waveforms may not be capable of achieving the desired aspect ratio, critical dimension, and uniformity (similar, for example, to conventional RF bias power).

The DC bias waveforms 32 of the periodic sequence 28 have been illustrated without showing applied source power (e.g., to ignite and sustain the plasma for generation of the ions 19) during the high aspect ratio process. An RF signal may be applied during the etching process and may overlap some or all of the periodic sequence 28. Additionally, one or both of the periodic sequence 28 and the RF signal may be pulsed. Because the RF signal and the periodic sequence 28 may be applied concurrently, the voltage 30 may be a superposition of the periodic sequence 28 and the coupling of the RF signal to the substrate 10. For example, this may be a combined RF power and DC bias waveform (e.g., as conceptually illustrated in FIG. 15). Here and in other example graphs of periodic sequences of DC bias waveforms the RF signal has been omitted for simplicity. However, it should be understood that an applied RF signal may at times fully or partially overlap the DC bias waveforms in any of the embodiments described herein.

The process 100 is a HARC etching process in various embodiments. In one specific example, the patterned surface 12 is a hardmask implemented as a 2.5 μm ACL layer containing contact holes overlying a 7.5 μm oxide layer (an underlying layer 14). The CD of the contact holes is about 70 nm and the plasma is generated at a chamber pressure of 10 mTorr using RF bias voltage −7.5 kV at a duty cycle of 20%, as shown in the periodic sequence 28 of FIG. 1.

FIG. 2 illustrates an example system for high aspect ratio etching that includes a DC waveform generator coupled to a lower electrode supporting a substrate within a plasma etching chamber in accordance with embodiments of the invention. The system of FIG. 2 may be a used to perform any of the processes described herein, such as the high aspect ratio etching process of FIG. 1, for example. Similarly labeled elements may be as previously described.

Referring to FIG. 2, a system 200 for high aspect ratio etching includes a plasma etching chamber 21 that is configured to contain a plasma 20 generated by applying an RF signal 24 to a source power coupling element 23. For example, the source power coupling element 23 may couple RF power from the RF signal 24 to gas 50 within the plasma etching chamber 21, some of which is excited to form the plasma 20. An RF power supply 22 may generate the RF signal 24 directly, or the RF signal 24 may be modified (such as through amplification, modulation, etc.) before being applied to the source power coupling element 23. In another embodiment, the RF power supply 22 and the source power coupling element 23 may also be attached to the substrate 10 or substrate support 25 along with the DC bias to form dual-power capacitively coupled plasma (CCP).

A substrate support 25 is configured to support a substrate 10 within the plasma etching chamber 21 (e.g., the substrate support 25 may be a wafer chuck and may also act as a lower electrode for use in generating the plasma 20 and/or etching underlying layers of the substrate 10).

The system 200 also includes a DC waveform generator 26 configured to supply DC bias signal to be amplified in a DC waveform amplifier 27 that is coupled to the substrate support 25. The DC waveform generator 26 and the DC waveform amplifier 27 is configured to generate a periodic sequence 28 of DC waveforms that is coupled to the substrate 10 (e.g., by applying the periodic sequence 28 to the substrate support 25). In some configurations, the system 200 may be configured to couple the source power to the substrate at the same time as the periodic sequence 28 (e.g., a high frequency source power such as between about 3 MHz and about 80 MHz).

A controller 29 is coupled to the DC waveform generator 26 and the RF power supply 22 (or in some embodiments to other components between the RF power supply 22 and the source power coupling element 23).

FIG. 3 illustrates a comparison between impact angles between different profiles of material deposited on the patterned surface during a high aspect ratio etching process in accordance with embodiments of the invention. The patterned surface profiles shown in FIG. 3 may be a schematic representation of other patterned surface profiles described herein, such as the those of the patterned surface of FIG. 1, for example. Similarly labeled elements may be as previously described.

Referring to FIG. 3, two patterned surface 12 protrusions are shown that have a different profile for the material buildup occurring during a high aspect ratio etching process. For example, the left shape may schematically represent a characteristic shape of material buildup when etching using RF bias power. This spearhead-shaped material buildup layer 318 produces somewhat steep impact angles (θ_{1,RF} and θ_{2,RF}) for the ions 19 that are being accelerated into the openings. In contrast, the material buildup layer 18 may schematically represent a characteristic shape of material buildup when using DC bias power (e.g., with greater than 20% duty cycle) and has a substantially rectangular (e.g., shovel-shaped) profile that produces much shallower impact angles (θ_{1,DC} and θ_{2,DC}).

Intuitively, the ions 19 that impact the sides (θ_{1,DC}) of the openings are delivered substantially vertically into the opening and have an increased probability of impacting the bottom of the opening (contributing to desired etching) rather than hitting the side of the opening. Similarly, the ions 19 that hit the top (θ_{2,DC}) of the patterned surface 12 protrusions are almost entirely reflected away from the patterned surface 12 and do not adversely impact the etching process. However, the ions 19 hitting the sides (θ_{1,RF}) of the spearhead-shaped material buildup layer 318 are deflected into the sides of the openings while the ions 19 hitting the top (θ_{2,RF}) bounce into adjacent spearhead-shaped material buildup layers 318 exacerbating the problem (e.g., as profile bow).

FIG. 4 illustrates waveform tuning of a high aspect ratio etching process with a qualitative graph of the etch rate and deposition rate versus the impact angle for various waveform shapes in accordance with embodiments of the invention. The waveform tuning of FIG. 4 may be used to tune any of the processes described herein, such as the high aspect ratio etching process of FIG. 1, for example. Similarly labeled elements may be as previously described.

Referring to FIG. 4, a qualitative graph 400 of etch rate as a function of impact angle is provided for different bias waveform shapes. Additionally, the deposition rate 44 is also shown (which is a straight line because the deposition process is facilitated by neutral species with thermal motion and is therefore isotropic). The points where the etch rates cross the deposition rate 44 are the characteristic angles (θ₁ and θ₂) discussed in reference to FIG. 3 where the steady-state profile angles θ₁ and θ₂ would establish during a dynamic etch process.

As shown, the RF etch rate 41 is below the deposition rate 44 for a large range of impact angles because of the large values of θ_{1,RF} and θ_{2,RF}. The impact angles define a sinusoidal RF etch window 45 between which the etch rate is higher than the deposition rate (there is a net etching occurring for those angles).

On the other side of the spectrum is the rectangular etch rate 42 which corresponds to substantially rectangular DC bias waveforms and has a much larger rectangular DC etch window 46. It can be difficult and expensive to generate high-fidelity rectangular DC waveforms with high voltage, so other waveform may be desirable. For example, a trapezoidal etch rate 43 is shown (very schematically) corresponding with a trapezoidal DC waveform (such as those shown in FIG. 1, for example) that has a trapezoidal process window 47 that is larger than the sinusoidal RF etch window 45, but not quite as large as the trapezoidal process window 47. One might imagine similar curves for other shapes, such as sawtooth, triangular, and others.

Deposition is isotropic (is not directionally dependent) because the deposition process is driven by reactive neutral species reacting with the surface. These reactive neutrals are not gaining any energy from the sheath between the plasma and the wafer surface (created by the applied bias voltage). The deposition rate can be modeled by the product of a factor s that is the sticking coefficient of the deposition species and a factor Γ that is the flux of deposition species. The deposition rate counteracts the etch rate and is therefore subtracted from the total etch rate.

On the other hand, the etch rate is anisotropic (is directional, controlled by direction the ions are accelerated by the applied bias voltage). It is much more complicated, including integrals over the ion energy and the impact angle of the ion flux multiplied by a function of the impact angle and the square root of the ratio of ion energy to reaction energy (a threshold energy, minimum required energy to etch the material) while taking into account the thermal energy.

The resulting curves show the angular dependance of relative rates of the etching and deposition where the deposition curve is constant (doesn't depend on the impact angle), and the etch curve begins below the deposition curve, crosses at a first impact angle (corresponding to the top of the feature), extends above for a time, and then crosses below the deposition curve again at a second impact angle (corresponding to the side of the feature). A wider impact angle window may advantageously widen the parameter space that can achieve positive etching and also results in a much higher peak etch rate.

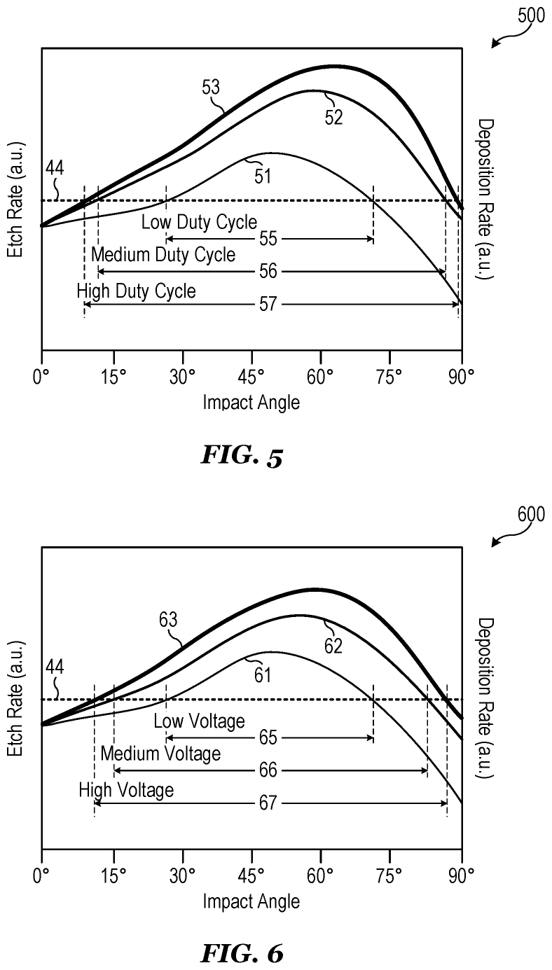

FIG. 5 illustrates duty cycle tuning of a high aspect ratio etching process with a qualitative graph of the etch rate versus the impact angle for various duty cycles in accordance with embodiments of the invention. The duty cycle tuning of FIG. 5 may be used to tune any of the processes described herein, such as the high aspect ratio etching process of FIG. 1, for example. Similarly labeled elements may be as previously described.

Referring to FIG. 5, a qualitative graph 500 of etch rate as a function of impact angle is provided for different duty cycles of a periodic sequence of DC waveforms (e.g., a trapezoidal waveform with a certain peak voltage applied at a certain frequency). As before, the deposition rate 44 is also shown. The points where the etch rates cross the deposition rate 44 are the characteristic angles (θ₁ and θ₂) discussed in reference to FIG. 3.

As can be seen in the qualitative graph 500, increasing the duty cycle also expands the impact angle window, the peak etch rate, and the area under the etch curve that is above the deposition curve (the total etch rate). When the bias duty cycle reduces, fewer energetic ions are delivered onto the wafer surface and hence the etch rate also reduces. At some relatively low duty cycle (e.g., 15%), the etch rate may look like the low duty cycle etch rate 51 and have a low duty cycle window 55 that is similar in expanse to the RF etch window 45 of FIG. 4, that is, potentially undesirable. For some medium duty cycle (e.g., about 20%) the medium duty cycle etch rate 52 becomes higher and the medium duty cycle window 56 broadens. In the same way, a high duty cycle (e.g., >20%) may result in high duty cycle etch rate 53 (even higher) and a broader high duty cycle window 57.

FIG. 6 illustrates voltage tuning of a high aspect ratio etching process with a qualitative graph of the etch rate versus the impact angle for various peak voltages in accordance with embodiments of the invention. The voltage tuning of FIG. 6 may be used to tune any of the processes described herein, such as the high aspect ratio etching process of FIG. 1, for example. Similarly labeled elements may be as previously described.

Referring to FIG. 6, a qualitative graph 600 of etch rate as a function of impact angle is provided for different peak voltages of a periodic sequence of DC waveforms (e.g., a trapezoidal waveform with a certain duty cycle applied at a certain frequency). Again, the deposition rate 44 is also shown and the etch rate intersections with the deposition rate 44 are the characteristic angles (θ₁ and θ₂) discussed in reference to FIG. 3. The reduction of the bias voltage leads to fewer energic ions which then results in reduced etch rate.

Holding other process parameters constant, increasing the peak voltage also expands the impact angle window, the peak etch rate, and the area under the etch curve that is above the deposition curve (the total etch rate). Analogous to before, at some relatively low voltage the low voltage etch rate 61 and the low voltage window 65 are small. Increasing the voltage to a relatively medium value and a relatively high value increase the etch rate and impact angle window, resulting in the larger medium voltage etch rate 62 and medium voltage window 66 and the even larger high voltage etch rate 63 and high voltage window 67, respectively.

Making a pristine (or at least substantially) rectangular wave (also known as a square wave despite the shape not always being “square”) may be prohibitively expensive. However, as demonstrated, desired uniformity may be achievable by appropriately tuning other values (e.g., duty cycle first, and also waveform shape and voltage). Therefore, at least for some applications, the DC bias waveform can advantageously be an arbitrary waveform and etch rate and impact angle window may be controlled using other parameters such as (e.g., primarily) duty cycle and applied voltage (or bias power).

Peak voltage may make intuitive sense as a parameter for rectangular waveforms as well as for many arbitrary waveforms that remain at the peak voltage for large portions each pulse (e.g., trapezoidal waveforms, near-rectangular waveforms, etc.). However, another useful parameter may be the power per cycle. For example, a triangular or sawtooth waveform may have a much higher peak voltage, but much less power per cycle than a more rectangular waveform. In these cases, a graph of etch rate as a function of impact angle for various power per cycle values may look similar to the qualitative graph 600.

It should be noted that the graph is schematic and qualitative. That is, the general effect of increasing the etch rate and the impact angle window by increasing the voltage is analogous to the general effect of increasing the duty cycle, but the specific effects may be different. In particular, waveform shape, duty cycle, and voltage may all affect the etch curves at different rates and by different amounts. There may also be some amount of interdependency between the parameters. Moreover, other application-specific factors may also affect the etch curves. Therefore, the specific values for process parameters that optimize the high aspect ratio etching process for a given application may depending the details of a given application.

FIG. 7 illustrates an example patterned surface and corresponding etched features where the openings in the patterned surface are holes in accordance with embodiments of the invention. The openings implemented as holes of FIG. 7 may be a specific implementation of other openings described herein, such as the openings of FIG. 1, for example. Similarly labeled elements may be as previously described.

Referring to FIG. 7, a patterned surface 12 overlying one or more underlying layers 14 (e.g., a dielectric layer such as an oxide, multiple layers such as ONO layers, etc.) includes hole openings 713, in this specific example. The hole openings 713 each have a hole diameter 71 and are separated from one another by a lateral hole pitch 72 and a vertical hole pitch 73 (although of course the diameters and pitches are not required to be the same). Further, the arrangement may also vary. For example, instead of a rectangular grid of hole openings 713, the hole openings 713 could also be arranged in a hexagonal grid, or any other arrangement.

The hole openings 713 may have a critical dimension (e.g., the hole diameter 71, but it could also be the pitch), less than 100 nm. In various embodiments, the critical dimension is less than about 80 nm, and is about 70 nm in one embodiment. Of course, the critical dimension could be even smaller, but there is a tradeoff between critical dimension and depth. The unit-less quantity aspect ratio, which is the quotient between depth and critical dimension, is used to describe these hole features instead. The aspect ratio of the hole openings 713 may be greater than about 75:1 in various embodiments and greater than about 100:1 in some embodiments.

FIG. 8 illustrates an example patterned surface and corresponding etched features where the openings in the patterned surface are trenches in accordance with embodiments of the invention. The openings implemented as trenches of FIG. 8 may be a specific implementation of other openings described herein, such as the openings of FIG. 1, for example. Moreover, in some embodiments, trenches may be included along with holes in the same patterned surface. Similarly labeled elements may be as previously described.

Referring to FIG. 8, the patterned surface 12 and the one or more underlying layers 14 are similar, but the openings in the patterned surface 12 are implemented as trench openings 813. The trench openings 813 are similar to the hole openings 713 of FIG. 7 except that they extend for some length, only having a trench width 81 and a trench pitch 82 (there is a start and an end, but it is typically significantly longer than the trench width 81 and is not shown here). While these simple structures are shown as examples (and also because these very dense periodic structures are important for various applications and may represent specific problems regarding high aspect ratio etching), the openings could be formed with any shape and pattern.

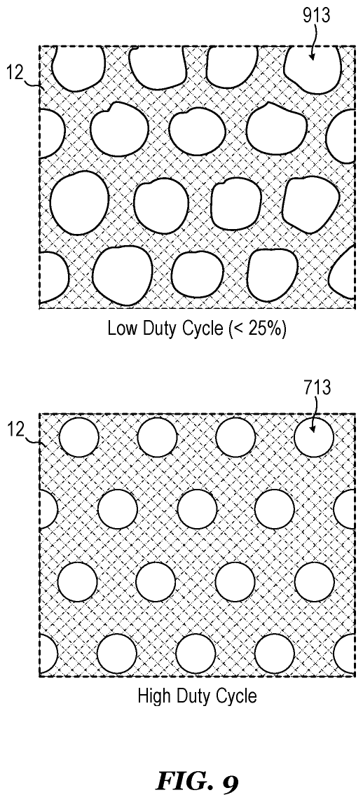

FIG. 9 schematically illustrates a comparison between uniform holes in a patterned surface and irregular holes in a patterned surface in accordance with embodiments of the invention. The irregular holes may represent features of a patterned surface formed using conventional or untuned high aspect ratio etching processes while the uniform holes of FIG. 9 may represent features of a patterned surface attainable using the processes described herein, such as the high aspect ratio process of FIG. 1, for example. Similarly labeled elements may be as previously described.

Referring to FIG. 9, and overhead view of a patterned surface 12 that includes hole openings 713 is contrasted with an overhead view of a patterned surface 12 that includes irregular hole openings 913. For example, the irregular hole openings 913 may be formed by a conventional etching process (e.g., using sinusoidal RF bias power) or using process parameters that are untuned (e.g., the etch rate curves result in an impact angle window that is small and causes spearhead-shaped material buildup during the high aspect ratio etching process). Such irregular hole openings 913 may undesirably result in nonuniform pattern transfer and even etch stop (e.g., from clogging) prior to reaching the target layer (or depth).

FIG. 10 illustrates an example qualitative graph of a periodic sawtooth sequence that includes sawtooth waveforms in accordance with embodiments of the invention. The periodic sawtooth sequence of FIG. 10 may be a specific implementation of other periodic sequences described herein, such as the periodic sequence of FIG. 1, for example. Similarly labeled elements may be as previously described.

Referring to FIG. 10, a qualitative graph 1000 shows a periodic sawtooth sequence 1028 including sawtooth waveforms 1032 that have a sawtooth duty cycle 1034 (greater than 20%) and an off time 1035. As shown, a voltage 1030 is applied resulting in small perturbations of the plasma potential 1033. As shown the sawtooth waveforms 1032 have a sawtooth non-vertical voltage transition 1038 on the tail of each waveform. Of course, the reverse of the sawtooth waveforms 1032 could also be used (with a linear voltage ramp first and a vertical return to the reference voltage second).

FIG. 11 illustrates an example qualitative graph of a periodic triangular sequence that includes triangular waveforms in accordance with embodiments of the invention. The periodic triangular sequence of FIG. 11 may be a specific implementation of other periodic sequences described herein, such as the periodic sequence of FIG. 1, for example. Similarly labeled elements may be as previously described.

Referring to FIG. 11, a qualitative graph 1100 shows a periodic triangular sequence 1128 including triangular waveforms 1132 that have a triangular duty cycle 1134 (greater than 20%) and an off time 1135. As shown, a voltage 1130 is applied resulting in small perturbations of the plasma potential 1133. In contrast to the sawtooth waveforms 1032 of FIG. 10, the triangular waveforms 1132 have two linear voltage transitions (triangular non-vertical voltage transitions 1138). Although the triangular waveforms 1132 are shown to be symmetric, this is not a requirement.

FIG. 12 illustrates an example qualitative graph of a mixed periodic sequence that includes a mixture of arbitrary waveforms in accordance with embodiments of the invention. The mixed periodic sequence of FIG. 12 may be a specific implementation of other periodic sequences described herein, such as the periodic sequence of FIG. 1, for example. Similarly labeled elements may be as previously described.

Referring to FIG. 12, a qualitative graph 1200 shows a mixed periodic sequence 1228 including mixed waveforms 1232 that have a combined duty cycle 1234 (greater than 20%) and an off time 1235. Different from the previous examples, the combined duty cycle 1234 and the combined off time 1235 are the total contributions of the mixed waveforms 1232 for each period 36. It is this total combined duty cycle 1234 that is greater than 20%. This may be advantageous for flexibility when dealing with issues such as substrate charging and heating. A voltage 1230 is applied resulting in small perturbations of the plasma potential 1233. While the mixed periodic sequence 1228 is shown as including sawtooth and rectangular waveforms, more waveforms or different waveforms could also be included.

For the mixed periodic sequence 1228, the frequency may mean different things. For example, here, the period 36 is shown to extend until the pattern repeats, but this is not a requirement. The period 36 could simply be the duration between the waveforms themselves. Additionally, there is no requirement that the waveforms themselves adhere to a pattern (the periodicity may be considered the that waveforms are periodically applied at a frequency, not that the specific waveforms have some kind of periodicity. As another example, a mixed periodic sequence may start with an extended chain of sawtooth waveforms and then transition to an extended chain of trapezoidal waveforms. An advantage of the waveforms being arbitrary enables any desired pattern (perhaps driven by specific conditions of a given application) as long as the duty cycle is greater than 20% and the specific process parameters are tuned appropriately.

FIG. 13 illustrates an example system for high aspect ratio etching where the system is implemented as a capacitively coupled plasma etching system in accordance with embodiments of the invention. The system of FIG. 13 may be a specific implementation of other high aspect ratio systems described herein, such as the system of FIG. 2, for example. Similarly labeled elements may be as previously described.

Referring to FIG. 13, a system 1300 for high aspect ratio etching includes a substrate support 25 (functioning as a lower electrode) configured to support a substrate 10 and an upper electrode 1323 configured to generate a capacitively coupled plasma 1320 (CCP) in a CCP etching chamber 1321 using an RF signal 24. An RF power supply 22 is coupled to the upper electrode 1323 and configured to apply the RF signal 24 to the upper electrode 1323. Alternatively, the RF signal 24 may instead be applied to the lower electrode (substrate support 25) and the upper electrode 1323 may be coupled to a reference voltage (e.g., ground voltage).

As before, a DC waveform generator 1326 should be connected to a DC waveform amplifier 27 that is coupled to the substrate support 25. In one embodiment, the DC waveform amplifier 27 includes a switch 91 and a voltage ramp circuit 92. The switch 91 may be any suitable type of switch, such as an electronic switch like a power transistor and the like. The DC power supply 26 may be coupled to the voltage ramp circuit 92 through the switch 91. The voltage ramp circuit 92 may be configured to generate a periodic sequence 28 of DC waveforms and coupled them to the substrate 10 through the substrate support 25 (acting as a lower electrode).

Gas (carrier, precursor, or otherwise) may be supplied into the CCP etching chamber 1321 through gas inlets 94 and exhausted through exhaust outlets 95. Optionally, the RF signal 24 and/or the periodic sequence 28 may be pulsed using an optional chopper circuit 99. For example, an optional chopper circuit 99 may be included between the RF power supply 22 and the upper electrode 1323 to generate RF pulses that are applied to the upper electrode 1323. Similarly, an optional chopper circuit 99 may be included between the DC waveform amplifier 27 and the substrate support 25 to create pulses of the periodic sequence 28.

Timing and parameters of the RF signal 24 and the periodic sequence 28 may be controlled by a controller 29 coupled to the DC waveform generator 1326. In some cases, the controller 29 may also be coupled to the RF power supply 22 (e.g., when it also includes amplification, modulation, and other functionality). When present, the controller 29 may also be coupled to one or both of the optional chopper circuits 99.

A processor 98 may also be included in the system (alternatively, the controller 29 may include memory and instructions or simply be hardwired to control the system). The processor 98 may be any suitable type of processor and may include a memory, or be configured to be coupled to a memory that can store instructions, that when executed by the processor 98, control the system.

FIG. 14 illustrates an example system for high aspect ratio etching where the system is implemented as a inductive coupled plasma etching system in accordance with embodiments of the invention. The system of FIG. 14 may be a specific implementation of other high aspect ratio systems described herein, such as the system of FIG. 2, for example. Similarly labeled elements may be as previously described.

Referring to FIG. 14, a system 1400 for high aspect ratio etching is similar to the system 1300 of FIG. 13, except the system 1400 includes RF antenna 1423 configured to generate an inductively coupled plasma 1420 (ICP) in an ICP etching chamber 1421 using the RF signal 24. The periodic sequence 28 is still coupled to the substrate support 25 using a DC waveform amplifier 27, as shown. Rather than the direct capacitive coupling of the upper electrode 1323, the RF antenna 1423 is coupled to the inductively coupled plasma 1420 indirectly through a dielectric 93 (e.g., a dielectric window). Of course, those skilled in the art will recognize that any suitable plasma etching system configuration may be used, so long as a periodic sequence of DC bias waveforms can be coupled to the substrate in the presence of a plasma.

FIG. 15 illustrates example qualitative graphs of an RF signal, a periodic sequence, and a combined RF power and DC bias waveform in accordance with embodiments of the invention. The combined RF power and DC bias waveform of FIG. 15 may be a conceptual representation on the applied power during any of the high aspect ratio etching processes described herein, such as the process of FIG. 1, for example. Similarly labeled elements may be as previously described.

Referring to FIG. 15, qualitative graphs 1500 show an RF signal 24, a periodic sequence 28 of DC bias waveforms 32, and a combined RF power and DC bias waveform 1539. As previously discussed, the RF signal 24 may be coupled to the plasma system (e.g., coupled to a source power coupling electrode, a lower electrode, or both) simultaneously with the DC bias waveforms 32. In this case, the resulting coupled voltage can be visualized as the combined RF power and DC bias waveform 1539. This combined waveform may be further modulated (e.g., pulsed) at its own duty cycle and frequency. In various embodiments, the combined RF power and DC bias waveform 1539 is applied with a frequency less than the frequency of the periodic sequence 28 and is applied with a frequency between about 100 Hz and about 100 kHz in some embodiments. The duty cycle of the combined RF power and DC bias waveform 1539 is between about 10% and about 80% in one embodiment.

FIG. 16 illustrates a method for high aspect ratio etching in accordance with embodiments of the invention. The method of FIG. 16 may be combined with other methods and processes and be performed using the systems and apparatuses as described herein. For example, the method of FIG. 16 may be combined with any of the embodiments of FIGS. 1-15. Although shown in a logical order, the arrangement and numbering of the steps of FIG. 16 are not intended to be limited. The method steps of FIG. 16 may be performed in any suitable order or concurrently with one another as may be apparent to a person of skill in the art.

Referring to FIG. 16, a method 1600 for high aspect ratio etching includes a step 1601 of generating a plasma in a plasma etching chamber containing a substrate comprising a patterned surface. The plasma may be generated by applying an RF signal to a source power coupling element (e.g., an upper electrode of a CCP system, an RF antenna of an ICP system, a microwave slot, etc.).

One or more underlying layers are then etched through openings in the patterned surface in step 1602 by coupling a periodic sequence comprising DC bias waveforms to the substrate (e.g., a substrate support, such as a wafer chuck, that also acts as a lower electrode). Each of the waveforms has a voltage ranging from a reference voltage to an absolute peak voltage (e.g., negative). The periodic sequence has a duty cycle greater than 20%. In some embodiments, the duty cycle is greater than about 50% and less than about 80%. As previously discussed, the duty cycle of the DC bias waveforms may each be used to tune the etch window and advantageously increase the etch rate as well as the mask uniformity.

The one or more underlying layers may include a dielectric (such as for a high aspect ratio contact etch, for example). The method 1600 for high aspect ratio etching may be used to form features having an aspect ratio of at least about 100:1 and a critical dimension less than about 100 nm (e.g., about 70 nm). In particular, conventional high aspect ratio etching processes may be incapable of achieving such high aspect ratio and low critical dimension while maintaining desired mask uniformity.

The frequency of the periodic sequence may be any suitable value. In some applications, the frequency may be relatively low frequency. In some embodiments, the periodic sequence is coupled to the substrate with frequency between about 100 kHz and about 3 MHz. In one embodiment, the frequency is about 400 kHz. In another embodiment, the frequency is about 800 kHz.

The absolute peak voltage may also be any suitable value. The absolute peak voltage is above about 7 kV in various embodiments. The peak voltage may also be negative (e.g., when accelerating positive ions toward the substrate). In this case, the peak voltage is a negative peak voltage, such as less than or equal to about −7 kV. The peak voltage may also be varied from waveform to waveform while coupling the periodic sequence to the substrate. As discussed in the foregoing, the voltage of the DC bias waveforms may be leveraged to tune the etch window and advantageously increase the etch rate as well as the mask uniformity.

In various embodiments, each of the DC bias waveforms includes a non-vertical voltage transition (e.g., a substantially linear slope, substantially exponential slope, etc.). For example, the DC bias waveforms may have one or several shapes, such as a trapezoidal waveform shape, triangular waveform shape, sawtooth waveform shape, or any arbitrary waveform shape as desired. In other embodiments, the DC waveforms have a rectangular shape. As previously discussed, the shape of the DC waveforms may be leveraged to tune the etch window and advantageously increase the etch rate as well as the mask uniformity.

The periodic sequence may also include a mixture of waveform shapes. That is, the periodic sequence may include DC waveforms with a first waveform shape (e.g., sawtooth) and additional DC waveforms with a second waveform shape (e.g., rectangular). Or course, other combinations are possible, such as trapezoidal and triangular, trapezoidal and sawtooth, etc. A mixture of waveform shapes may be advantageous if the etch rate profile is time dependent during the etching process.

A DC waveform generator may be used to generate the periodic sequence of waveforms, which may be further amplified by an amplifier. For example, the amplified DC waveform may be coupled to a lower electrode supporting the substrate. For certain DC waveforms, the DC waveform generator may advantageously be less complex and costly to implement. For example, although useful in some applications, it may be relatively difficult and expensive to form rectangular waveforms, while other waveform types may be easier and less costly to generate (especially if the voltage ramping requirements are relatively gradual and other parameters are tuned to provide the desired etch rate and mask uniformity). In some embodiments, the DC waveform generator includes a switch and a voltage ramp circuit (which may or may not be tunable).

Example embodiments of the invention are summarized here. Other embodiments can also be understood from the entirety of the specification as well as the claims filed herein.

Example 1. A method for high aspect ratio etching, the method including: generating a plasma in a plasma etching chamber containing a substrate including a patterned surface; and etching one or more underlying layers through openings in the patterned surface by coupling a periodic sequence including DC bias waveforms to the substrate, each of the DC bias waveforms including a non-vertical voltage transition and voltage ranging from a reference voltage to a negative peak voltage, the periodic sequence having a duty cycle greater than 20%.

Example 2. The method of example 1, where the periodic sequence is coupled to the substrate with frequency between about 100 kHz and about 3 MHz, and where the negative peak voltage is less than or equal to about −7 kV.

Example 3. The method of one of examples 1 and 2, where the duty cycle is greater than about 50% and less than about 80%.

Example 4. The method of one of examples 1 and 3, where the non-vertical voltage transition is substantially linear.

Example 5. The method of example 4, where the DC bias waveforms include a trapezoidal waveform shape, a sawtooth waveform shape, or a triangular waveform shape.

Example 6. The method of one of examples 1 to 5, where the patterned surface is a patterned hardmask surface.

Example 7. The method of one of examples 1 to 6, where the method is a high aspect ratio contact (HARC) etching process, the one or more underlying layers comprising a dielectric layer.

Example 8. The method of one of examples 1 to 7, where the DC bias waveforms each have a first waveform shape, and where periodic sequence further includes additional DC bias waveforms, each having a second waveform shape that is different from the first waveform shape.

Example 9. A method for high aspect ratio dielectric etching, the method including: generating a plasma in a plasma etching chamber containing a substrate including a hardmask overlying a dielectric by applying a radio frequency (RF) signal to a source power coupling element; and etching the dielectric through openings in the hardmask to form features having an aspect ratio of at least about 100:1 by coupling a periodic sequence including direct current (DC) waveforms to a lower electrode supporting the substrate with frequency between about 100 kHz and about 3 MHz, each of the DC bias waveforms having voltage ranging from a reference voltage to a negative peak voltage less than or equal to about −7 kV, the periodic sequence having a duty cycle greater than 20%.

Example 10. The method of example 9, where the duty cycle is greater than about 50% and less than about 80%.

Example 11. The method of one of examples 9 and 10, where the DC bias waveforms include a trapezoidal waveform shape, sawtooth waveform shape, or a rectangular waveform shape.

Example 12. The method of one of examples 9 to 11, where the openings comprising a critical dimension less than about 100 nm.

Example 13. The method of one of examples 9 to 12, where the hardmask comprises an amorphous carbon layer (ACL) or a tungsten silicide (WSi) layer.

Example 14. The method of one of examples 9 to 13, where the DC bias waveforms each have a first waveform shape, and where periodic sequence further includes additional DC bias waveforms, each having a second waveform shape that is different from the first waveform shape.

Example 15. The method of example 14, where the first waveform shape is a sawtooth waveform shape and the second waveform shape is a rectangular waveform shape.

Example 16. The method of one of examples 9 to 15, where the negative peak voltage of the DC bias waveforms is varied during the periodic sequence.

Example 17. A system for high aspect ratio etching including: a plasma etching chamber, a radio frequency (RF) power supply configured to generate an RF signal; a source power coupling element coupled to the RF power supply and configured to generate a plasma within the plasma etching chamber using the RF signal; a lower electrode disposed in the plasma chamber and configured to support a substrate; a direct current (DC) power supply configured to supply DC voltage; a DC waveform generator coupled between the lower electrode and the DC power supply, the DC waveform generator configured to etch the substrate by generating a periodic sequence of DC waveforms having voltage ranging from a reference voltage to an absolute peak voltage of at least about 7 kV, the periodic sequence having a frequency between about 100 kHz and about 3 MHz and a duty cycle greater than 20%; and a controller coupled to the DC waveform generator and configured to cause the DC waveform generator to generate the periodic sequence.

Example 18. The system of example 17, where the DC waveform generator includes a switch and a voltage ramp circuit.

Example 19. The system of one of examples 17 and 18, where the source power coupling element is an upper electrode, the lower electrode being configured to support the substrate between the upper electrode and the lower electrode, and where the plasma is a capacitively coupled plasma.

Example 20. The system of one of examples 17 and 18, where the source power coupling element is the lower electrode and the plasma is a capacitively coupled plasma.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for high aspect ratio etching, the method comprising:
generating a plasma in a plasma etching chamber containing a substrate comprising a patterned surface; and
etching one or more underlying layers through openings in the patterned surface by coupling a periodic sequence comprising direct current (DC) bias waveforms to the substrate, each of the DC bias waveforms including a non-vertical voltage transition and voltage ranging from a reference voltage to a negative peak voltage, the periodic sequence having a duty cycle greater than 20%.

2. The method of claim 1,
wherein the periodic sequence is coupled to the substrate with frequency between about 100 kHz and about 3 MHz, and
wherein the negative peak voltage is less than or equal to about −7 kV.

3. The method of claim 1, wherein the duty cycle is greater than about 50% and less than about 80%.

4. The method of claim 1, wherein the non-vertical voltage transition is substantially linear.

5. The method of claim 4, wherein the DC bias waveforms comprise a trapezoidal waveform shape, a sawtooth waveform shape, or a triangular waveform shape.

6. The method of claim 1, wherein the patterned surface is a patterned hardmask surface.

7. The method of claim 1, wherein the method is a high aspect ratio contact (HARC) etching process, the one or more underlying layers comprising a dielectric layer.

8. The method of claim 1,
wherein the DC bias waveforms each have a first waveform shape, and
wherein periodic sequence further comprises additional DC bias waveforms, each having a second waveform shape that is different from the first waveform shape.

9. A method for high aspect ratio dielectric etching, the method comprising:
generating a plasma in a plasma etching chamber containing a substrate comprising a hardmask overlying a dielectric by applying a radio frequency (RF) signal to a source power coupling element; and
etching the dielectric through openings in the hardmask to form features having an aspect ratio of at least about 100:1 by coupling a periodic sequence comprising direct current (DC) bias waveforms to a lower electrode supporting the substrate with frequency between about 100 kHz and about 3 MHz, each of the DC bias waveforms having voltage ranging from a reference voltage to a negative peak voltage less than or equal to about −7 kV, the periodic sequence having a duty cycle greater than 20%.

10. The method of claim 9, wherein the duty cycle is greater than about 50% and less than about 80%.

11. The method of claim 9, wherein the DC bias waveforms comprise a trapezoidal waveform shape, a sawtooth waveform shape, or a rectangular waveform shape.

12. The method of claim 9, wherein the openings comprising a critical dimension less than about 100 nm.

13. The method of claim 9, wherein the hardmask comprises an amorphous carbon layer (ACL) or a tungsten silicide (WSi) layer.

14. The method of claim 9,
wherein the DC bias waveforms each have a first waveform shape, and
wherein periodic sequence further comprises additional DC bias waveforms, each having a second waveform shape that is different from the first waveform shape.

15. The method of claim 14, wherein the first waveform shape is a sawtooth waveform shape and the second waveform shape is a rectangular waveform shape.

16. The method of claim 9, wherein the negative peak voltage of the DC bias waveforms is varied during the periodic sequence.

17. A system for high aspect ratio etching comprising:
a plasma etching chamber,
a radio frequency (RF) source power supply configured to generate an RF signal;
a source power coupling element coupled to the RF power supply and configured to generate a plasma within the plasma etching chamber using the RF signal;
a lower electrode disposed in the plasma chamber and configured to support a substrate;
a direct current (DC) power supply configured to supply DC voltage;
a DC waveform generator coupled between the lower electrode and the DC power supply, the DC waveform generator configured to etch the substrate by generating a periodic sequence of DC waveforms having voltage ranging from a reference voltage to an absolute peak voltage of at least about 7 kV, the periodic sequence having a frequency between about 100 kHz and about 3 MHz and a duty cycle greater than 20%; and
a controller coupled to the DC bias waveform generator and configured to cause the DC bias waveform generator to generate the periodic sequence.

18. The system of claim 17, wherein the DC bias waveform generator comprises a switch and a voltage ramp circuit.

19. The system of claim 17, wherein the source power coupling element is an upper electrode, the lower electrode being configured to support the substrate between the upper electrode and the lower electrode, and wherein the plasma is a capacitively coupled plasma.

20. The system of claim 17, wherein the source power coupling element is the lower electrode and the plasma is a capacitively coupled plasma.
